(19) United States
(12) Patent Application Publication
(10) Pub. No.: US 2016/0270233 A1
(43) Pub. Date: Sep. 15, 2016

(54) PRINTED CIRCUIT BOARD AND METHOD OF MANUFACTURING THE SAME

(71) Applicant: SAMSUNG ELECTRO-MECHANICS CO., LTD., Suwon-si (KR)

(72) Inventor: Hyung Gi HA, Suwon-si (KR)

(73) Assignee: SAMSUNG ELECTRO-MECHANICS CO., LTD., Suwon-si (KR)

(21) Appl. No.: 14/966,547

(22) Filed: Dec. 11, 2015

(30) Foreign Application Priority Data
Mar. 13, 2015 (KR) 10-2015-0034901

(51) Int. Cl. H05K 1/18; H05K 1/09; H05K 3/46; H05K 1/11; H05K 1/02

(52) U.S. Cl. CPC H05K 1/185; H05K 1/115; H05K 1/0298; H05K 3/4697; H05K 1/09

(57) ABSTRACT

Disclosed is a printed circuit board in which an electronic component may be embedded and a method of manufacturing the same. The printed circuit board may include a core layer including a cavity having a supporting part, an electronic component seated on the supporting part, a first and a second insulating layers to cover an upper and a lower portions of the core layer, and vias connecting circuits formed in the core layer and on the insulating layers to each other, whereby a process of manufacturing a printed circuit board having an electronic component embedded therein may be simplified.

### CROSS-REFERENCE TO RELATED APPLICATION(S)

This application claims the priority and benefit under 35 USC 119(a) of Korean Patent Application No. 10-2015-0034901 filed on Mar. 13, 2015 in the Korean Intellectual Property Office, the entire disclosure of which is incorporated herein by reference for all purposes.

### BACKGROUND

1. Field

The following description relates to a printed circuit board in which an electronic component may be embedded and a method of manufacturing the same.

2. Description of Related Art

In accordance with the development of mobile devices such as, for example, smartphones, tablet PCs, and wearable devices, demand for miniaturization and slimness of electronic devices has increased.

To facilitate this, technology for embedding active and passive elements in a printed circuit board has been continuously developed. By embedding the active and passive elements in the printed circuit board, an overall size of electronic devices and the number of components mounted on the printed circuit board have been reduced.

However, unlike the passive elements, the size of the active elements is greater than 1*1. Therefore, when cavities, in which the active elements are embedded, are formed in the printed circuit board, warpage of the printed circuit board tends to increase. Thus, a solution for the warpage defects is required.

In addition, when a cavity is machined in a printed circuit board having an active element or a passive element embedded therein, a tape is required to fix the embedded element after machining the cavity.

The chip embedded printed circuit board has been manufactured by attaching the tape to one surface of the cavity, embedding the element into the cavity, and separately forming an epoxy resin in upper and lower portions of the cavity. In particular, in the case of the active element, there is always a risk of warpage defects caused by the upper and lower portions of the cavity not being balanced due to a chip bump and a redistribution layer (RDL).

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, there is provided a printed circuit board having a simplified manufacturing process by seating an electronic component on a supporting part when the electronic component is embedded in a cavity of the printed circuit board, and a method of manufacturing the same.

In another general aspect, there is provided a printed circuit board including a core layer including a cavity having a supporting part, an electronic component seated on the supporting part, a first and a second insulating layers to cover an upper and a lower portions of the core layer, and vias connecting circuits formed in the core layer and on the insulating layers to each other.

The supporting part may be configured to affix the electronic component.

The core layer may be prepreg including an inorganic filler and an inorganic reinforcement material.

The electronic component may have a bump to electrical connection with an external circuit.

The printed circuit board may include a bump via to electrically connected to the bump.

The supporting part may be configured to protrude toward an inner portion of the cavity.

The electronic component may be inserted into the cavity.

A distance of the supporting layer from an inner wall of the cavity may be based on the location of the bump.

The printed circuit board may include a bump via configured to be electrically connected to the bump, and the bump via may be configured to supply power to the electronic component.

The bump via may be further configured to transmit a signal to the electronic component and to receive a signal from the electronic component.

In another general aspect, there is provided a method of manufacturing a printed circuit board, the method including forming a cavity in a core layer, forming a supporting part in a lower portion of the cavity, and embedding an electronic component in the cavity.

The electronic component may be fixed to an inner wall of the cavity using an adhesive.

The manufacturing method may include simultaneously laminating an upper layer and a lower layer on upper and lower surfaces of the core layer, respectively, after the embedding of the electronic component in the cavity, and the upper layer may include an upper insulating layer and an upper copper foil layer and the lower layer may include a lower insulating layer and a lower copper foil layer.

The core layer may be prepreg including an inorganic filler and an inorganic reinforcement material.

Other features and aspects will be apparent from the following detailed description, the drawings, and the claims.

### BRIEF DESCRIPTION OF DRAWINGS

FIG. 1 is a diagram illustrating an example of a printed circuit board.

FIG. 2 is a diagram illustrating an example of an operation of forming a cavity having a supporting part in a core layer in a method of manufacturing a printed circuit board.

FIG. 3 is a diagram illustrating an example of an operation of mounting an electronic component in the cavity in the method of manufacturing a printed circuit board.

FIG. 4 is a diagram illustrating an operation of simultaneously laminating prepreg including insulating layers and copper foil layers on and below the core layer in the method of manufacturing a printed circuit board.

FIG. 5 is a diagram illustrating an example of an operation of forming vias connected to bumps of the electronic component in the method of manufacturing a printed circuit board.

FIG. 6 is a diagram illustrating an example of an operation of forming an external circuit pattern in the method of manufacturing a printed circuit board.

FIG. 7 is a diagram illustrating an example of an operation of forming a solder resist in the method of manufacturing a printed circuit board.

Throughout the drawings and the detailed description, unless otherwise described or provided, the same drawing reference numerals refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the systems, apparatuses and/or methods described herein will be apparent to one of ordinary skill in the art. The progression of processing steps and/or operations is described as an example; the sequence of operations is not limited to that set forth herein and may be changed as is known in the art, with the exception of steps and/or operations that necessarily occur in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure is thorough, complete, and conveys the full scope of the disclosure to one of ordinary skill in the art.

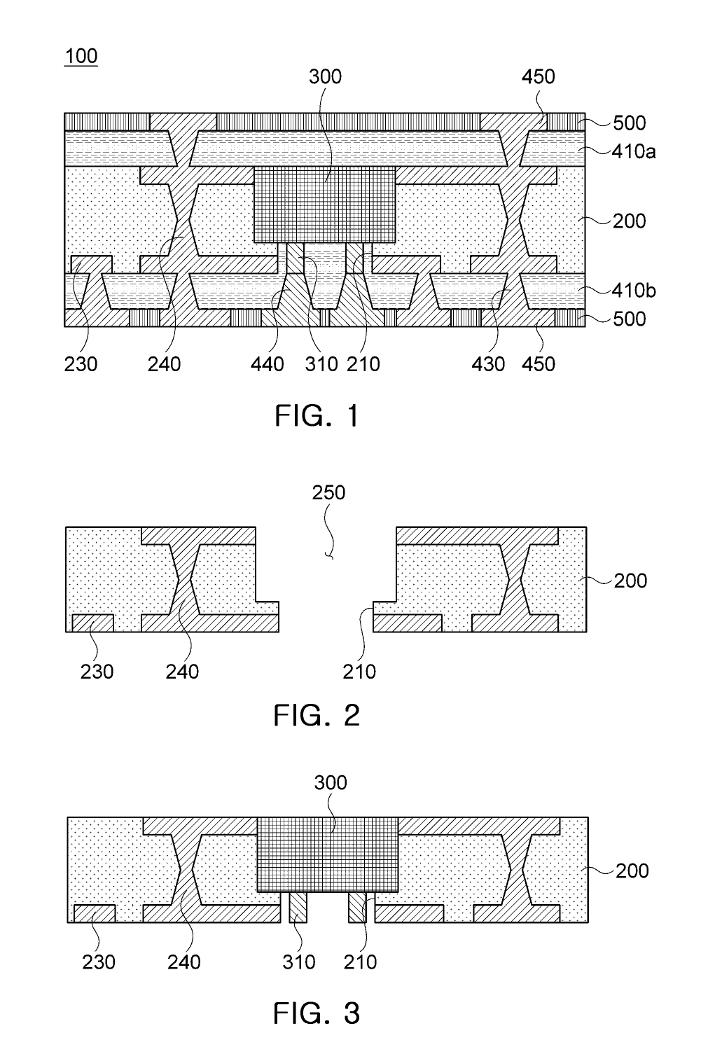

FIG. 1 is a diagram illustrating an example of a printed circuit board. FIG. 2 is a diagram illustrating an example of a cross-sectional view illustrating an operation of forming a cavity having a supporting part in a core layer in a method of manufacturing a printed circuit board.

Referring to FIGS. 1 and 2, a printed circuit board 100 may include a core layer 200 in which a cavity 250 having a supporting part 210 is formed. An electronic component 300 is inserted into the cavity 250 to be seated on the supporting part 210. Insulating layers 410a and 410b are formed to cover upper and lower portions of the core layer 200. Vias 240, 430, and 440 connect circuits 230 and 450, formed on the core layer 200 and the insulating layers 410a and 410b, to each other.

The insulating layers may include an upper insulating layer 410a and a lower insulating layer 410b. The circuits may include an inner layer circuit 230 formed in the core layer 200 and outer layer circuits 450 formed on the insulating layers. The vias may include an inner layer via 240 formed in the core layer, and an outer layer via 430 and a bump via 440 formed in the insulating layers.

In addition, solder resists 500 may be formed to protect the outer layer circuits 450.

The supporting part 210 may be provided by adjusting a distance protruding from an inner wall of the cavity 250 depending on a position of a bump 310 of the electronic component 300. The supporting part 210 may allow the electronic component 300 to be fixed without using adhesive tape when embedding the electronic component 300.

The electronic component 300 may be electrically connected to the printed circuit board 100 through the bump via 440, and the bump via 440 may be electrically connected to the bump 310 of the electronic component 300.

In an example, a prepreg i.e., fabric reinforcement that has been pre-impregnated with a resin system, may be used as a material of the core layer 200. The prepreg may have an inorganic reinforcement material such as, for example, glass fiber impregnated in a varnish including an inorganic filler. Other material of the core layer 200 are considered to be well within the scope of the present disclosure.

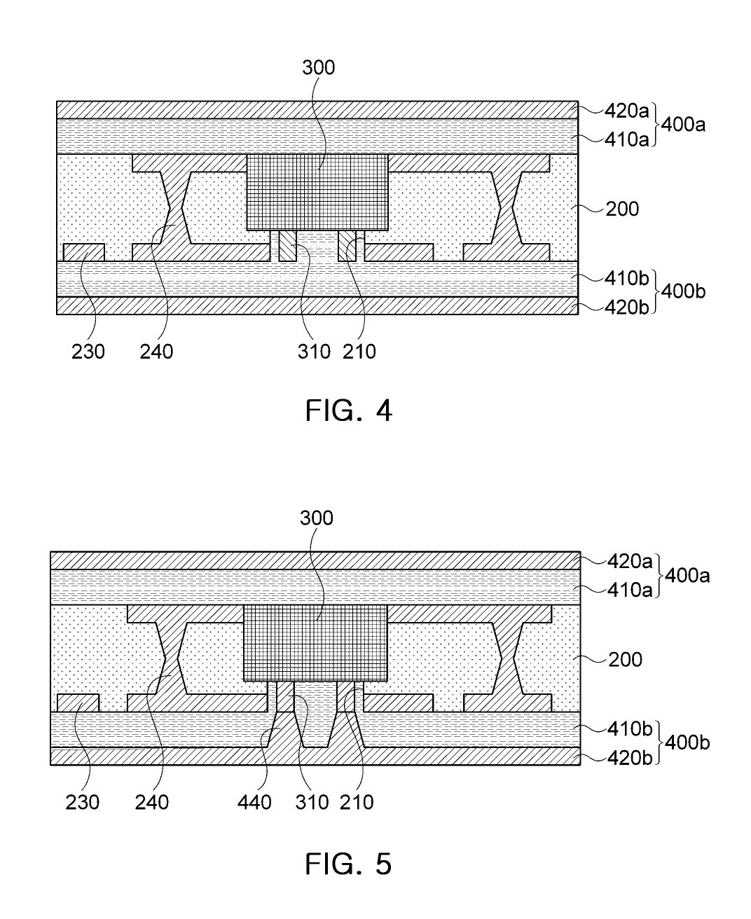

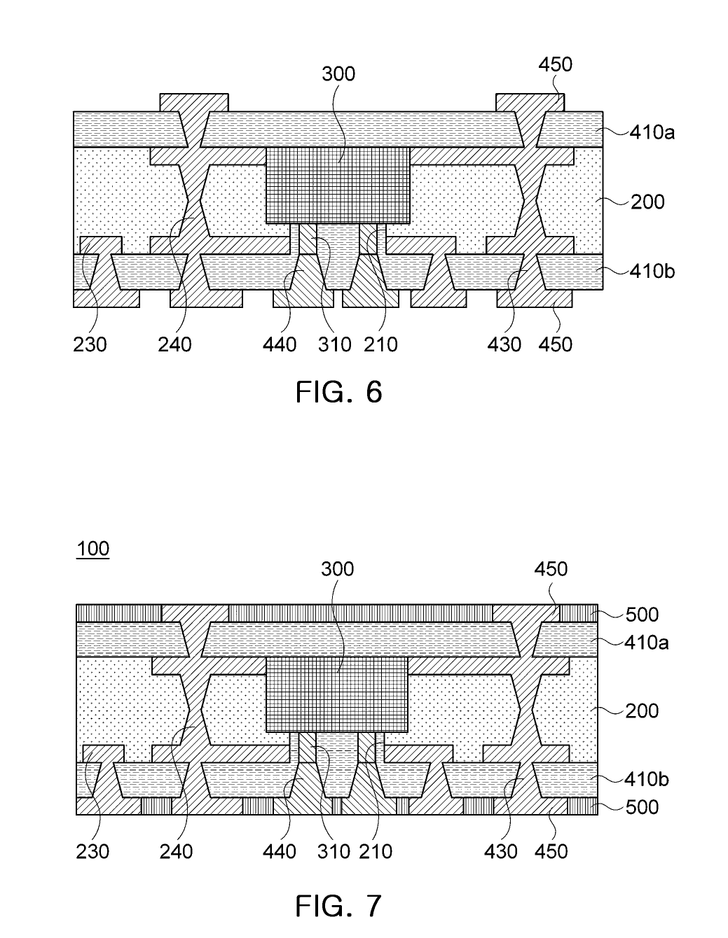

FIG. 2 is a diagram illustrating an operation of forming the cavity having the supporting part in the core layer in the method of manufacturing a printed circuit board. FIG. 3 is a diagram illustrating an example of an operation of mounting the electronic component in the cavity in the method of manufacturing a printed circuit board. FIG. 4 is a diagram illustrating an example of an operation of simultaneously laminating the prepreg including insulating layers and copper foil layers on and below the core layer in the method of manufacturing a printed circuit board. FIG. 5 is a diagram illustrating an example of an operation of forming the vias connected to the bumps of the electronic component in the method of manufacturing a printed circuit board. FIG. 6 is a diagram illustrating an example of an operation of forming an external circuit pattern in the method of manufacturing a printed circuit board. FIG. 7 is a diagram illustrating an example of an operation of forming the solder resist in the method of manufacturing a printed circuit board.

The method of manufacturing a printed circuit board may include forming a cavity having a supporting part formed in a lower portion thereof in a core layer and embedding an electronic component in the cavity.

The method of manufacturing a printed circuit board may further include forming an inner layer circuit and an inner layer via in the core layer, simultaneously laminating an upper layer including an upper insulating layer and an upper copper foil layer and a lower layer including a lower insulating layer and a lower copper foil layer on upper and lower surfaces of the core layer after embedding the electronic component in the cavity, forming an outer layer via to electrically connected a bump of the electronic component, forming outer layer circuits, and forming solder resists for protecting the outer layer circuits.

Referring to FIG. 2, the method of manufacturing a printed circuit board may include forming a cavity 250 in a core layer 200. The cavity 250 may have a supporting part 210 formed in a lower portion of the cavity 250. An inner layer via 240 and an inner layer circuit 230 may be formed in the core layer 200.

The cavity 250 may be utilized as a space for embedding the electronic component 300, and the supporting part 210 may fix the electronic component 300 in the cavity 250. The material of the core layer 200, may be prepreg as described above. But the material of the core layer 200 is not limited thereto.

In an example, the cavity may be formed in the core layer 200 using processes, such as, for example, laser drilling. The cavity 250 having a step created by the supporting part 210 may be formed by performing laser drilling in two stages or adjusting an etching amount during the laser drilling.

In another example, the cavity 250 may also be formed by a lithography process, and the cavity 250 having the step created by the supporting part 210 may be formed by performing an etching process in two stages.

To machine the cavity, a copper foil of a portion of the core layer 200 to be machined may be etched by the lithography process, and the cavity may be machined using laser drilling. When a circuit is formed in the cavity 250 of the core layer 200, the size of the circuit may be adjusted in consideration of the step of the supporting part 210 of the core layer. When the cavity 250 is machined using the laser drilling, since the copper foil of the core layer 200 is left on the supporting port 210, the supporting part 210 may reflect the laser and not be machined, thereby forming the supporting part 210.

Referring to FIG. 3, the method of manufacturing a printed circuit board may include an operation of embedding the electronic component 300 in the cavity in which the supporting part 210 has been formed. The electronic component 300 may include the bump 310 for an electrical connection with the printed circuit board. A pick and place machine (not illustrated) may be used to embed the electronic component 300 in the cavity.

In an example, the electronic component 300 may be fixed to an inner wall of the cavity by an adhesive such as, for example, an epoxy, which is applied to the outside of the electronic component 300. The lamination process may be performed by the supporting part 210 and the adhesive without using separate adhesive tape.

Referring to FIG. 4, the method of manufacturing a printed circuit board may include an operation of simultaneously laminating an upper layer 400a and a lower layer 400b on upper and lower surfaces of the core layer 200, respectively. The upper layer 400a may include an upper insulating layer 410a and an upper copper foil layer 420a and the lower layer 400b may include a lower insulating layer 410b and a lower copper foil layer 420b.

In an example, prepreg may be used for the upper insulating layer 410a and the lower insulating layer 410b.

In a board having an embedded electronic component, adhesive tape may be used on the lower surface of the cavity to fix the electronic component in the cavity. In a lamination process, after a build-up layer is laminated on the upper surface of the cavity, the adhesive tape is removed and the build-up layer needs to be laminated on the lower surface of the cavity.

However, in the printed circuit board 100 disclosed herein, since the electronic component 300 is fixed by the supporting part 210 of the cavity 250, the upper layer 400a and the lower layer 400b may be simultaneously laminated. The operations of attaching and removing the adhesive tape, which is generally required in manufacturing the board having an embedded electronic component is eliminated.

The upper layer 400a may include the upper insulating layer 410a and the upper copper foil layer 420a and the lower layer 400b may include the lower insulating layer 410b and the lower copper foil layer 420b. The upper insulating layer 410a and the lower insulating layer 410b may each include a polymer resin.

The polymer resin flowing out from the upper insulating layer 410a and the lower insulating layer 410b may be provided in an empty space of the cavity 250 by temperature and pressure in the operation of simultaneously laminating the upper layer and the lower layer. When the polymer resin is cured, the electronic component 300 embedded in the cavity 250 may be more firmly fixed.

Referring to FIG. 5, the method of manufacturing a printed circuit board may include an operation of forming a bump via 440 electrically connected to a bump 310 of the electronic component 300 embedded in the cavity 250.

The bump via 440 may be formed to be electrically connected to the bump 310 of the electronic component 300 and may be used to supply power to the electronic component 300 or transmit and receive a signal to and from the electronic component 300. In an example, the bump via 440 may be formed by a laser drill process and an etching process using a lithography. The laser drill process may use a laser, such as, for example, a CO₂ laser, a Yttrium Aluminum Garnet (YAG) laser.

Referring to FIG. 6, the method of manufacturing a printed circuit board may include an operation of forming an outer layer via 430 and outer layer circuits 450.

The outer layer via 430 may be formed by a laser drill process and an etching process using a lithography, and the outer layer circuits 450 may be formed by patterning the upper copper foil layer 420a and the lower copper foil layer 420b of FIG. 5.

The operation of forming the bump via 440 and the operation of forming the outer layer via 430 may be simultaneously performed.

Referring to FIG. 7, the method of manufacturing a printed circuit board may include an operation of forming solder resists 500.

The solder resists 500 may serve as protective layers for protecting the outer layer circuits 450 that are exposed externally.

In an example, a structure of four or more layers may be formed by additionally laminating the insulating layer and the copper foil layer on the printed circuit board. The operation of forming the solder resists may be performed after forming final outer layer circuits.

As set forth above, the printed circuit board has the supporting part formed in the cavity, and the operations of attaching and detaching the adhesive tape are omitted during the operations of embedding the electronic component in the cavity and laminating the build-up layer. Thus, the upper layer and the lower layer may be simultaneously laminated, whereby the manufacturing process is simplified.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
a core layer comprising a cavity having a supporting part;
an electronic component seated on the supporting part;
a first and a second insulating layers to cover an upper and a lower portions of the core layer; and
vias connecting circuits formed in the core layer and on the insulating layers to each other.

2. The printed circuit board of claim 1, wherein the supporting part is configured to affix the electronic component.

3. The printed circuit board of claim 1, wherein the core layer is prepreg including an inorganic filler and an inorganic reinforcement material.

4. The printed circuit board of claim 1, wherein the electronic component has a bump to electrical connection with an external circuit.

5. The printed circuit board of claim 4, further comprising a bump via to electrically connected to the bump.

6. The printed circuit board of claim 1, wherein the supporting part is configured to protrude toward an inner portion of the cavity.

7. The printed circuit board of claim 1, wherein the electronic component is inserted into the cavity.

8. The printed circuit board of claim 4, wherein a distance of the supporting layer from an inner wall of the cavity is based on the location of the bump.

9. The printed circuit board of claim 4, further comprising a bump via configured to be electrically connected to the bump, and the bump via is configured to supply power to the electronic component.

10. The printed circuit board of claim 9, wherein the bump via is further configured to transmit a signal to the electronic component and to receive a signal from the electronic component.

11. A method of manufacturing a printed circuit board, the method comprising:
forming a cavity in a core layer;
forming a supporting part in a lower portion of the cavity; and
embedding an electronic component in the cavity.

12. The method of claim 11, wherein the electronic component is fixed to an inner wall of the cavity using an adhesive.

13. The manufacturing method of claim 11, further comprising:
simultaneously laminating an upper layer and a lower layer on upper and lower surfaces of the core layer, respectively, after the embedding of the electronic component in the cavity, and
the upper layer comprises an upper insulating layer and an upper copper foil layer and the lower layer comprises a lower insulating layer and a lower copper foil layer.

14. The method of claim 11, wherein the core layer is prepreg comprising an inorganic filler and an inorganic reinforcement material.
